(19) United States
(12) Patent Application Publication
(10) Pub. No.: US 2013/0008256 A1
(43) Pub. Date: Jan. 10, 2013

(54) METHOD FOR REDUCING CONTENT OF FOREIGN MOLECULES DISSOLVED IN A PRESSURE TRANSFER LIQUID OF A PRESSURE MEASURING TRANSDUCER

(75) Inventors: Andreas Rossberg, Bad Sackingen (DE); Olaf Textor, Lorrach (DE); Thomas Uehlin, Schopfheim (DE)

(73) Assignee: Endress + Hauser GmbH + Co. KG, Maulburg (DE)

(21) Appl. No.: 13/636,828

(22) PCT Filed: Feb. 28, 2011
(86) PCT No.: PCT/EP2011/052908

§ 371 Date: Sep. 24, 2012

(30) Foreign Application Priority Data
Apr. 8, 2010 (DE) 102010003708.7

(51) Int. Cl. G01L 7/08; G01R 3/00; B01D 53/02; G01L 9/12; B01D 15/00

(52) U.S. Cl. 73/724; 73/723; 210/660; 95/90; 29/595

(57) ABSTRACT

A method for reducing the content of foreign molecules in gaseous or liquid form dissolved in a pressure transfer liquid of a pressure measuring transducer. A pressure receiving chamber is closed by an isolating diaphragm. A pressure measuring chamber is connected to the pressure receiving chamber, and a pressure sensor arranged in the pressure measuring chamber, in which the liquid serves to fill an inner space of the pressure measuring transducer formed by the pressure receiving chamber is provided. The pressure measuring chamber is connected therewith, and transfers an external pressure acting on the isolating diaphragm to the pressure sensor in measurement operation. The liquid is brought into contact with at least one adsorptive body, and foreign molecules dissolved in the liquid are bound to the adsorptive bodies by adsorption.

The invention relates to a method for reducing content of foreign molecules in gaseous or liquid form dissolved in a pressure transfer liquid of a pressure measuring transducer.

Pressure transfer liquids are applied in a large number of pressure measuring transducers in pressure measuring technology, in order to bring a pressure to be measured to a pressure sensor. Liquids, such as e.g. silicone oils, which are as incompressible as possible and have thermal coefficients of expansion as small as possible, are preferably used as pressure transfer liquids.

Typically, pressure measuring transducers have a pressure receiving chamber closed outwardly by an isolating diaphragm; the pressure receiving chamber is connected via a passageway to a pressure measuring chamber, in which the pressure sensor is located. The pressure receiving chamber, the pressure measuring chamber and the passageway are filled with the pressure transfer liquid, which in measurement operation transmits an external pressure to be measured acting on the isolating diaphragm to the pressure sensor.

Examples of this are pressure measuring transducers, in which semiconductor sensors, e.g. silicon chips having doped resistance elements, are applied as pressure sensors. Usually, semiconductor sensors comprise a membrane-like pressure sensor chip, which is supported laterally in the pressure measuring chamber. Semiconductor sensors are, as a rule, very sensitive and are therefore not directly exposed to a medium, whose pressure is to be measured.

Pressure measuring transducers having upstream pressure transfer means are an additional example. In measurement operation, the pressure transfer means has a pressure receiving chamber arranged at a measuring location and closed by an isolating diaphragm; the pressure receiving chamber is connected via a pressure transfer line to the pressure measuring chamber of the pressure measuring transducer; the pressure sensor is located in the pressure measuring chamber; the pressure measuring chamber is arranged remotely from the measuring location.

In such case, it is of special importance for the accuracy of measurement of the pressure measuring transducer that the pressure transfer liquid contains as few foreign molecules dissolved in gaseous or liquid form as possible. Gases and/or liquids dissolved in the pressure transfer liquid acting on the isolating diaphragm, can, under certain circumstances, especially at high temperatures and/or low pressures, lead to gas bubbles forming very suddenly in the liquid, which drastically changes the transfer behavior of the pressure transfer liquid. Depending on the amount of trapped foreign molecules, this results, in certain circumstances, in considerable temperature dependent and/or pressure dependent measurement errors. For instance, water molecules contained in liquid form or in gaseous form as steam in the liquid are especially common and problematic. Due to its vapor pressure increasing exponentially with temperature, water forms steam bubbles at relatively low temperatures very suddenly under certain circumstances.

Currently, to remove foreign molecules dissolved in the pressure transfer liquid, the pressure transfer liquid is regularly pretreated in a vacuum distillation method, before the liquid is introduced, as a rule under vacuum conditions, into the pressure measuring transducer.

Vacuum distillation methods have the disadvantage that the distillation temperature is limited by the thermal stability of the pressure transfer liquid.

Additionally, through the vacuum distillation method, an increasing portion of additional components is withdrawn from the liquid with rising distillation temperature. This unavoidably leads to an increase in the viscosity of the liquid, which is disadvantageous for low loss pressure transfer; the increase in the viscosity of the liquid can likewise only be counteracted by limiting the distillation temperature.

Due to limitations for the distillation temperature, a residual content of foreign molecules, which cannot be made smaller, remains dissolved in the pressure transfer liquid even after the distillation method.

Foreign molecules, such as e.g. water and air are, however, not only contained in the pressure transfer liquid provided for filling, but, can also cling on the inner walls of the measuring transducer to be filled, and find their way into the pressure transfer liquid from there. In order to decrease the number of foreign molecules clinging on the inner walls, the internal spaces are preferably baked before being filled; the internal spaces are heated at high temperature under vacuum for a short time; this loosens the clinging foreign molecules from the inner wall and then they are sucked out via the applied vacuum. However, a residual content of foreign molecules clinging on the inner walls also remains here; this residual content can be released in dissolved form into the pressure transfer liquid after the filling.

It is an object of the invention to provide a method for reducing content of foreign molecules in gaseous or liquid form dissolved in a pressure transfer liquid of a pressure measuring transducer

For this, the invention resides in a method for reducing content of foreign molecules in gaseous or liquid form dissolved in a pressure transfer liquid of a pressure measuring transducer,
which has a pressure receiving chamber closed by an isolating diaphragm;
which has a pressure measuring chamber connected to the pressure receiving chamber;
which has a pressure sensor arranged in the pressure measuring chamber; and
in which the liquid serves to fill an inner space of the pressure measuring transducer formed by the pressure receiving chamber and the pressure measuring chamber connected thereto, and to transfer an external pressure acting on the isolating diaphragm to the pressure sensor in measurement operation, wherein
the liquid is brought into contact with at least one adsorptive body, and
foreign molecules dissolved in the liquid are bound to the adsorptive bodies by adsorption.

In a preferred embodiment, the adsorptive bodies comprise zeolite.

Additionally, the invention includes a first embodiment of the method of the invention, wherein
the adsorptive bodies, in a pretreatment method for pretreating the liquid for filling the pressure measuring transducer, are introduced as granular material into the liquid, where the adsorptive bodies then adsorb foreign molecules;
the liquid is separated from the adsorptive bodies containing the adsorbed foreign molecules; and
the inner space of the pressure measuring transducer to be filled is filled with the liquid, which has been separated from the adsorptive bodies.

Additionally, the invention includes a second embodiment of the method of the invention, wherein
the adsorptive bodies have a particle size, which is small compared to the dimensions of the inner space of the pressure measuring transducer to be filled;
the adsorptive bodies are introduced into the liquid in a pretreatment method for pretreating the liquid for filling the pressure measuring transducer; and
the inner space of the pressure measuring transducer is filled with the liquid containing the adsorptive bodies.

Additionally, the invention comprises a third embodiment of the method of the invention, wherein
the adsorptive bodies have a particle size, which is small compared to the dimensions of the inner space of the pressure measuring transducer to be filled;
the adsorptive bodies are introduced into the inner space of the pressure measuring transducer to be filled; and
the inner space is filled with the liquid.

Additionally, the invention includes a fourth embodiment of the method of the invention, wherein
the pressure measuring transducer has at least one hollow space adjoining the inner space to be filled;
adsorptive bodies are introduced into the hollow spaces;
the hollow spaces are separated from the inner space by a partition, which is permeable to the liquid and impermeable to the adsorptive bodies; and
the inner space and the hollow spaces are filled with the liquid.

Additionally, the invention includes an embodiment of the third or the fourth embodiment, wherein the pressure transfer liquid is pretreated in a pretreatment method before filling the pressure measuring transducer with this liquid, in which pretreatment method:
adsorptive bodies are introduced into the liquid and adsorb foreign molecules dissolved therein;
the liquid is separated from the adsorptive bodies and the foreign molecules bound to the adsorptive bodies by adsorption; and
the separated liquid, which is free of adsorptive bodies, is used for filling.

Additionally, the invention comprises a pressure measuring transducer manufactured with the method of the invention, wherein the pressure measuring transducer has
a pressure receiving chamber closed by an isolating diaphragm,
a pressure measuring chamber connected to the pressure receiving chamber,
a pressure sensor arranged in the pressure measuring chamber, and
an inner space formed by the pressure receiving chamber and the pressure measuring chamber connected thereto and filled with a pressure transfer liquid; and
wherein the liquid contains adsorptive bodies,
whose particle size is small compared to the dimensions of the inner space filled with the liquid, and
which serve to bind foreign molecules dissolved in the liquid to themselves by adsorption.

Additionally, the invention comprises a pressure measuring transducer manufactured with the method of the invention, wherein the pressure measuring transducer has
a pressure receiving chamber closed by an isolating diaphragm,
a pressure measuring chamber connected to the pressure receiving chamber,
a pressure sensor arranged in the pressure measuring chamber, and
at least one hollow space adjoining the inner space formed by the pressure receiving chamber and the pressure measuring chamber connected thereto, wherein,
adsorptive bodies are arranged in the hollow spaces;
the inner space and hollow spaces are filled with the pressure transfer liquid; and
the hollow spaces are separated from the inner space by a partition, which is permeable to the liquid and impermeable to the adsorptive bodies.

In a further development of the last mentioned pressure measuring transducer, this has
at least one hollow space arranged in a diaphragm bed of the isolating diaphragm, which diaphragm bed adjoins the pressure receiving chamber;
at least one hollow space adjoining the pressure measuring chamber;
at least one hollow space adjoining a pressure transfer line connecting the pressure receiving chamber with the pressure measuring chamber; and/or
a hollow space, which is arranged in an end of a filling opening of the pressure measuring transducer and adjoins the inner space of the pressure measuring transducer.

Additionally, the invention comprises a pressure measuring transducer manufactured with the method of the invention, wherein the pressure measuring transducer has
a pressure receiving chamber closed by an isolating diaphragm,
a pressure measuring chamber connected to the pressure receiving chamber, and
a pressure sensor arranged in the pressure measuring chamber; wherein
the inner space formed by the pressure receiving chamber and the pressure measuring chamber connected thereto is filled with a pressure transfer liquid; and
at least one adsorptive body in the form of a molded body is arranged in the inner space or an adjoining hollow space.

In a first further development of the last mentioned pressure measuring transducer, one of the adsorptive bodies is an adsorptive body that is arranged in a hollow space, which is closed to the environment, that adjoins the pressure receiving chamber on its side lying opposite the isolating diaphragm, and that is embodied as a diaphragm bed for the isolating diaphragm.

In a second further development of the last named pressure measuring transducer, one of the adsorptive bodies is a tubular adsorptive body inserted in a line connecting the pressure receiving chamber to the pressure measuring chamber. In a third further development of the last named pressure measuring transducer, one of the adsorptive bodies is a displacement body inserted in the inner space of the pressure measuring transducer.

In a further development of the last named further development, the adsorptive body inserted as a displacement body is provided with electrical connections, via which a capacitance of the adsorptive body dependent on the state of the pressure transfer liquid soaking the adsorptive body can be measured by means of a capacitance measuring circuit connected thereto.

The method of the invention offers the advantage that the adsorptive bodies permanently remove the foreign molecules from the liquid; the foreign molecules are then no longer available for forming gas bubbles in the pressure measuring transducer.

The invention and further advantages will now be explained in greater detail based on the figures of the drawing, in which seven examples of embodiments are presented. Equal elements are provided with the equal reference characters in the figures. The figures of the drawing show as follows:

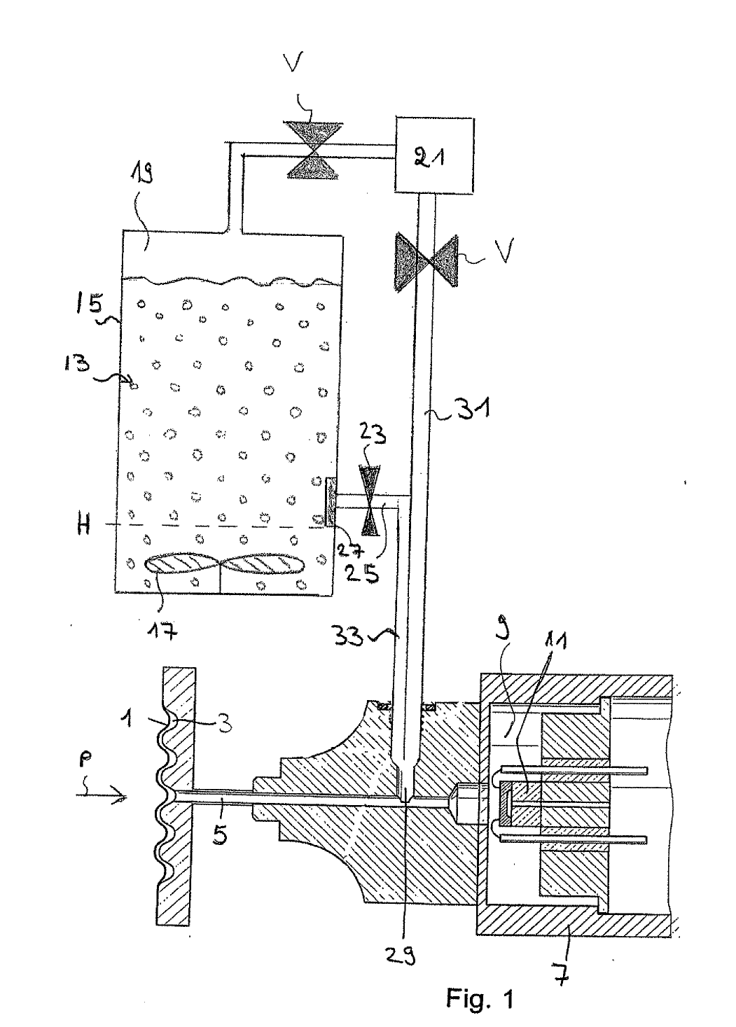

FIG. 1 schematically, a pressure measuring transducer with a thereto connected apparatus for pretreating the pressure transfer liquid and for filling the pressure measuring transducer;

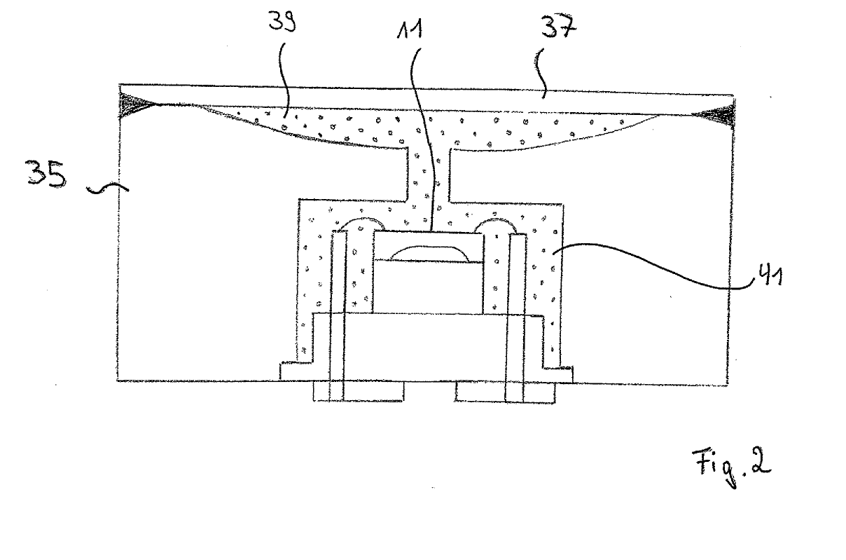

FIG. 2 a pressure measuring transducer having an inner space filled with a pressure transfer liquid, wherein adsorptive bodies are introduced into the inner space;

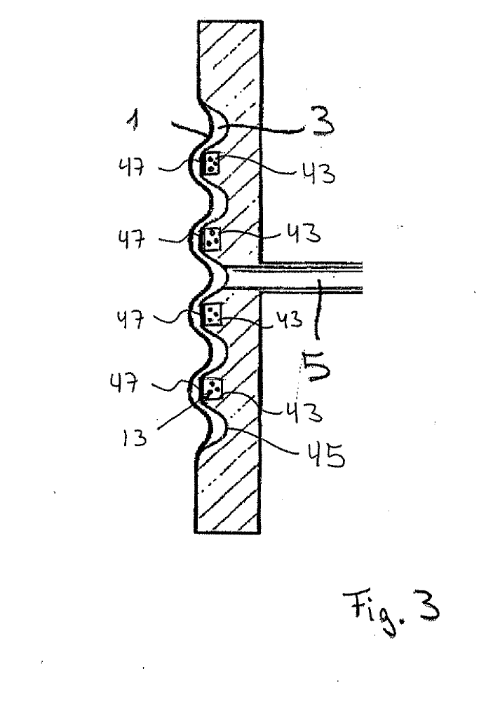

FIG. 3 the pressure transfer means of the pressure measuring transducer of FIG. 1, wherein hollow spaces containing adsorptive bodies are provided in the diaphragm bed of the isolating diaphragm;

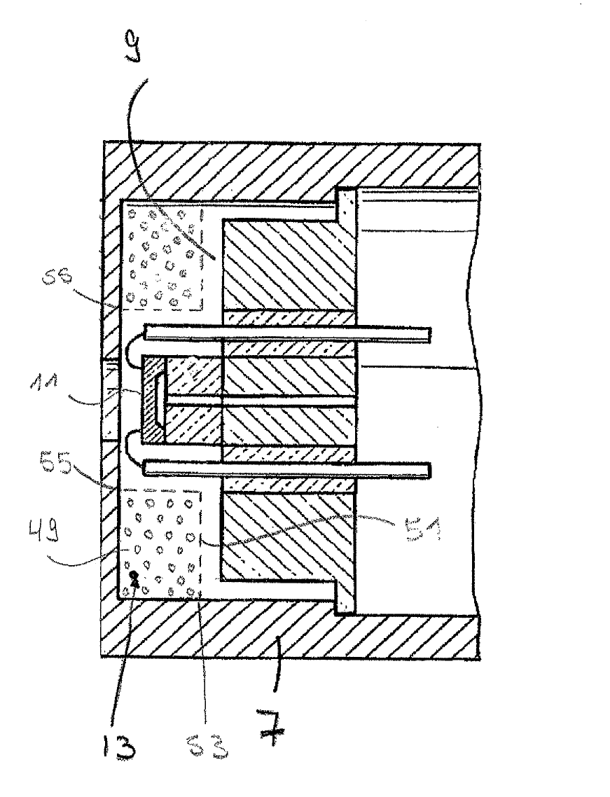

FIG. 4 the measuring transducer housing of the pressure measuring transducer of FIG. 1, in which a hollow space containing adsorptive bodies is provided in the pressure measuring chamber;

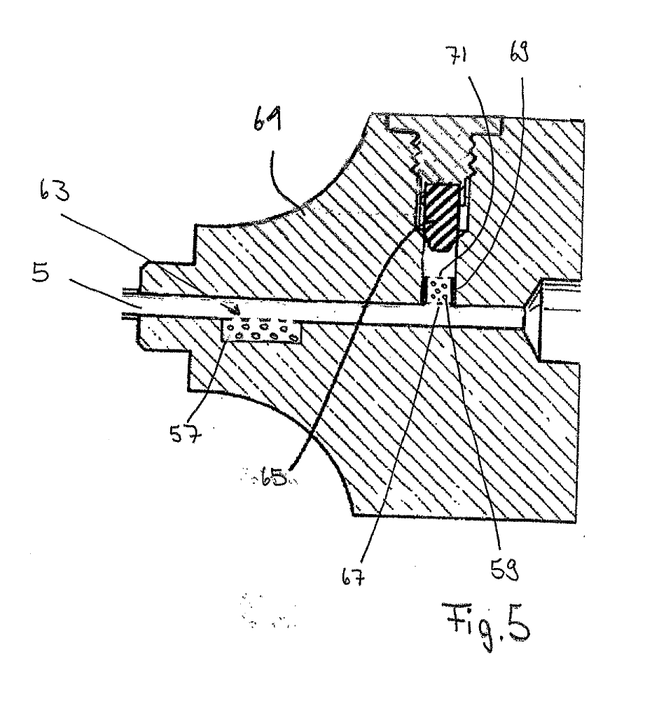

FIG. 5 the connection piece of the pressure measuring transducer of FIG. 1, with a hollow space with adsorptive bodies arranged in the filling opening and a hollow space with adsorptive bodies bordering the pressure transfer line;

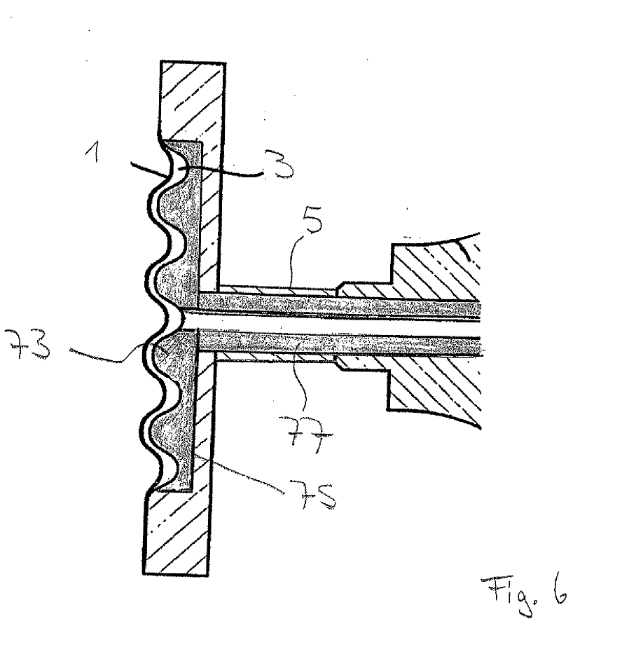

FIG. 6 the pressure transfer means of the pressure measuring transducer of FIG. 1, in which the diaphragm bed of the isolating diaphragm is formed by an adsorptive body formed as a molded part and arranged under the pressure receiving chamber, and an additional tubular adsorptive body arranged in the line of the pressure transfer means; and

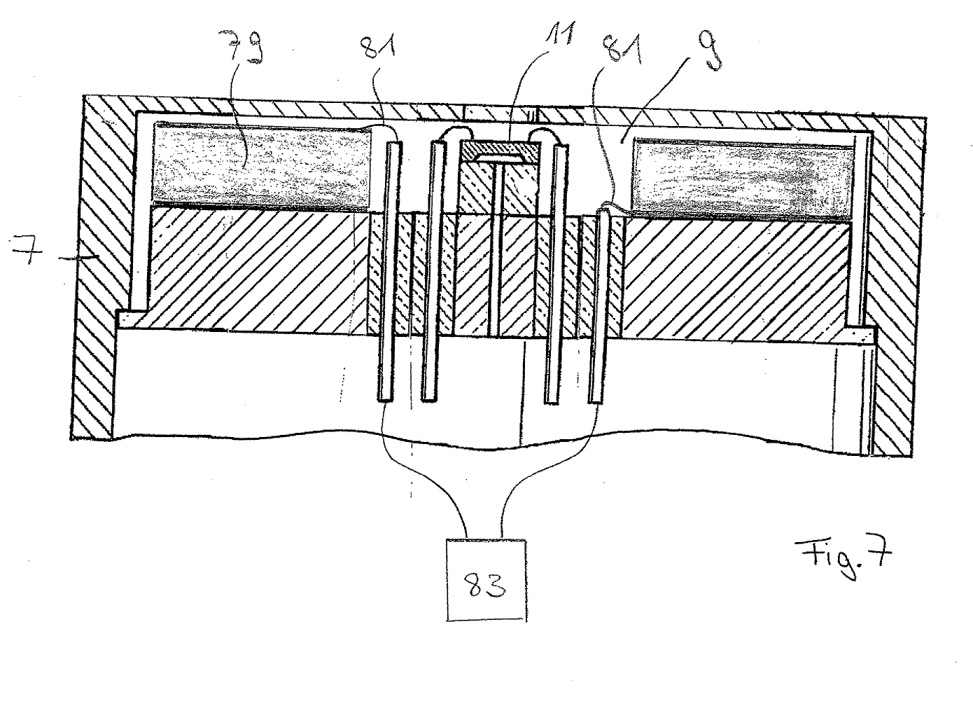

FIG. 7 an example of an adsorptive body applied as a displacement body.

FIG. 1 shows, schematically, a pressure measuring transducer together with an apparatus connected thereto for pretreating the pressure transfer liquid and for filling the pressure measuring transducer.

The pressure measuring transducer has a pressure transfer means having a pressure receiving chamber 3 closed by an isolating diaphragm 1. Pressure receiving chamber 3 is connected via a pressure transfer line 5 to a pressure measuring chamber 9 enclosed in a measuring transducer housing 7 located remotely from the pressure receiving chamber 3. In pressure measuring chamber 9, a pressure sensor 11, e.g. a semiconductor sensor, is arranged, which in measurement operation serves to measure an external pressure p acting on isolating diaphragm 1. For this, the inner space of the pressure measuring transducer formed by pressure receiving chamber 3, line 5 and pressure measuring chamber 9 is filled with a pressure transfer liquid, which in measurement operation serves to transfer the pressure p acting on isolating diaphragm 1 to pressure measuring chamber 9 and therewith to pressure sensor 11 located therein.

The pressure measuring transducer shown here represents only one example of a pressure measuring transducer, in which the invention is applicable. The invention is also applicable in connection with differently embodied pressure measuring transducers, which have an inner space filled with a pressure transfer liquid for transmitting a pressure to be registered metrologically to a pressure sensor arranged in the inner space.

The pressure transfer liquid is preferably a hydraulic liquid, e.g. a silicone oil, which is as incompressible as possible and which has a thermal coefficient of expansion, which is as small as possible.

Ordinarily marketed, pressure transfer liquids always contain a residual content of foreign molecules, especially water and air, in gaseous or liquid form dissolved therein. This residual content cannot be withdrawn from the liquid due to limitations of the distillation temperature even using a vacuum distillation method. In addition to water molecules, foreign molecules especially well soluble in silicone oils, such as e.g. oxygen, nitrogen and carbon dioxide play an important role here.

According to the invention, the content of foreign molecules in liquid or gaseous form dissolved in the pressure transfer liquid is reduced by bringing the liquid into contact with at least one adsorptive body 13 and, via this contact, foreign molecules dissolved in the liquid are bound to the adsorptive bodies 13 by adsorption. In this way, the adsorbed foreign molecules are withdrawn from the liquid and cannot form gas bubbles in the liquid in measurement operation.

The adsorptive bodies 13 preferably comprise zeolite. Zeolites are alumino-silicates, whose crystal lattice has a cage structure with numerous hollow spaces, which are accessible from all sides through pores.

Zeolites are obtainable both as a granular material as well as sintered formed bodies with a relatively freely selectable form. Since zeolites can only adsorb molecules, which can pass through their pores, they are suited especially well to selectively adsorb the disturbing foreign molecules, especially water, oxygen, nitrogen and carbon dioxide, contained in pressure transfer liquids. The adsorption takes place at room temperature so that this method is also suitable for liquids, which have very low thermal stability. Since the exclusively targeted, low molecular weight materials are removed from the liquid by adsorptive bodies 13, the targeted disturbing content of low molecular weight foreign molecules in pressure transfer liquids is reduced through this method without the viscosity of the liquid being detectably increased.

The method of the invention can be executed at different stages of the manufacturing process of the pressure measuring transducer.

In a first variant of the invention, the method is executed in the form of a liquid pretreatment method, to which the liquid is subjected before it is filled into the inner space of the pressure measuring transducer. This variant can be executed, for example, with the apparatus illustrated in FIG. 1 for pretreating the pressure transfer liquid and for filling the pressure measuring transducer.

In such case, the pressure transfer liquid is filled into a supply container 15, in which adsorptive bodies 13 are preferably introduced in the form of a fine grained granulate. Preferably arranged in supply container 15 is mixer 17, which mixes the content of supply container 15 at the beginning of the pretreatment method and thereby effects a uniform distribution of the adsorptive bodies 13 in the liquid as indicated in FIG. 1.

Preferably, an inner space 19 of supply container 15 remaining above the liquid level is evacuated via a vacuum pump 21 connected thereto via a valve V. In this way, foreign molecules emerging upwardly from the liquid are sucked out and an intake of foreign molecules from the environment is prevented.

Adsorptive bodies 13 remove foreign molecules from the liquid until either dissolved foreign molecules are no longer contained in the liquid or the loading capacity of adsorptive bodies 13 is reached.

The adsorbed foreign molecules are then bound to adsorptive bodies 13 and can accordingly be separated from the liquid together with adsorptive bodies 13. For this, the force of gravity is preferably utilized, which causes the adsorptive bodies 13 to sink to the floor of supply container 15. After adsorptive bodies 13 sink, a layer of adsorptive bodies 13 is located on the floor of supply container 15. The height H of the layer, as indicated by the dashed line in FIG. 1, is a function of the dimensions, of supply container 15 and the amount of adsorptive bodies 13 introduced earlier therein. Located above this layer is the liquid separated from the adsorptive bodies 13. The liquid freed from the adsorbed foreign molecules can now be removed, for example, via an outflow 25 equipped with a controllable valve 23 and arranged above the height H of the layer of adsorptive bodies.

Alternatively, a filter 27 can be provided in front of outflow 25, in order to prevent adsorptive bodies 13 from leaving supply container 15.

For filling the inner space of the pressure measuring transducer, outflow 25 is preferably connected directly to a filling apparatus (here shown schematically only), via which the liquid freed from the adsorbed foreign molecules is introduced into the inner space of the pressure measuring transducer. The pressure measuring transducer has for this a filling opening 29, via which the inner space to be filled is accessible.

A number of different filling apparatuses and filling methods known from the state of the art can be applied for the filling. Preferably, as shown in FIG. 1, the filling occurs under vacuum. For this, the vacuum pump 21 is connected to the inner space via an evacuation line 31 equipped with a valve V and opening into filling opening 29 for evacuating the inner space. Then, the inner space is filled with the liquid freed from the adsorbed foreign molecules via outflow 25 fed into filling line 33 opening into filling opening 29. Then, the filling apparatus is removed and the filling opening 29 sealed pressure, and gas, tightly by a closure (not shown here).

To the extent that adsorptive particles 13 are applied, which have a particle size, which is small compared to the dimensions of the inner space of the pressure measuring transducer to be filled, a second variant of the invention can alternatively be applied, in which the inner space is filled with liquid containing adsorptive bodies 13. In this case, the inner space is preferably directly filled with the liquid containing adsorptive bodies 13 after the introduction of the adsorptive bodies 13 into the liquid. Also, a homogeneous distribution of adsorptive bodies 13 is preferably effected here by mixer 17. In contrast to the earlier described method, the filling here, however, occurs during the mixing procedure or immediately thereafter, so that the adsorptive bodies 13 have no time to settle on the floor of supply container 15. Filter 27 is not used in this case.

FIG. 2 shows an example of a pressure measuring transducer filled with a liquid containing adsorptive particles 13. As an alternative to the example of an embodiment illustrated in FIG. 1, a pressure measuring transducer lacking an upstream pressure transfer means is presented here. This embodiment has a compact measuring transducer housing 35, on whose front side a pressure receiving chamber 39 closed outwardly by an isolating diaphragm 37 is located. Pressure receiving chamber is connected via a short passageway extending in the interior of transducer housing 35 to a pressure measuring chamber 41 arranged in measuring transducer housing 35. Pressure sensor 11 is located in pressure measuring chamber 41.

The same end result as regards the filled pressure measuring transducer is alternatively also achievable by introducing the adsorptive bodies 13 into the inner space before filling the pressure measuring transducer. The pressure measuring transducer is then subsequently filled with pressure transfer liquid. Also in such case, the adsorptive bodies 13 must naturally have a particle size small compared to the dimensions of the inner space to be filled, in order to assure unhindered pressure transfer through the liquid. Also in this way, adsorptive bodies 13 get into the liquid and bind foreign molecules dissolved in the liquid by adsorption.

In such case, the liquid, with which the inner space of the pressure measuring transducer containing adsorptive bodies 13 is filled, can naturally be supplementally subjected to the pretreatment method described above, in which the liquid, before it is used for filling, is mixed with adsorptive bodies 13, which are separated together with the adsorbed foreign molecules from the liquid before the filling. Then, the pressure measuring transducer is filled with the liquid, which is pretreated using the pretreatment method in this way and is free of adsorptive bodies. This variant offers the advantage that the content of foreign molecules dissolved in the liquid clearly already reduced by the pretreatment method is still further reduced by adsorptive bodies 13 contained in the pressure measuring transducer.

Alternatively to the introduction of adsorptive bodies 13 into the inner space of the pressure measuring transducer, adsorptive bodies 13 can also be introduced in one or more hollow spaces, serving here to accommodate adsorptive bodies likewise formed as granulate and connected to the inner space of the pressure measuring transducer to be filled with the pressure transfer liquid. The hollow spaces are closed to the inner space by a partition, such as e.g. a metal grate, which is permeable to the liquid but is impermeable to adsorptive bodies 13. The foreign molecules dissolved in the liquid located in the hollow space(s) are also here bound to adsorptive bodies 13 through adsorption, and are thus permanently removed from the liquid.

Since adsorptive bodies 13, in such case, remain in the hollow spaces, they bring about no degradation of the pressure transmitting properties of the liquid in the inner space. This variant is also especially applicable in pressure measuring transducers, which have inner spaces with small dimensions. Since adsorptive particles 13 do not penetrate into the adjoining inner space, the particle size of adsorptive bodies 13 here does not need to be small compared to the dimensions of the inner space of the pressure transducer.

The hollow space(s) can be arranged at different locations in the pressure measuring transducer.

Thus, for example, as shown in FIG. 3, at least one hollow space 43 can be sunk into the diaphragm bed 45 of isolating diaphragm 1. FIG. 3 shows four hollow spaces 43 in the diaphragm bed 45 of isolating diaphragm 1 of the pressure measuring transducer illustrated in FIG. 1. Adsorptive bodies 13 are located in each hollow space 43. Hollow spaces 43 face directly into the pressure receiving chamber 3 and are closed toward pressure receiving chamber 3 by the partition 47, which is permeable to liquid and impermeable to adsorptive bodies 13. For the manufacture of this variant, adsorptive bodies 13 are introduced into the hollow spaces 43 beforehand, which are then sealed by partition 47, e.g. a metal grate. Then isolating diaphragm 1 is welded in place. Preferably, pressure receiving chamber 3 and the adjoining hollow spaces 43 are heated strongly once under vacuum before the filling of the liquid. This procedure, which is referred to as baking, causes at least a large part of foreign molecules, especially possible residual moisture, clinging to the interior of the pressure transfer means, to be released, so that it can be sucked out. Adsorptive bodies 13 comprising zeolite offer, in such case, the advantage that they can, in given cases, freely release already adsorbed molecules at high temperatures, especially at temperatures above 250° C., so that these molecules are likewise sucked out and therefore the adsorptive bodies 13 reach their maximum adsorptive capacity before contact with the filled pressure transfer liquid.

FIG. 4 shows an additional hollow space 49—here arranged in pressure measuring chamber 9 of the pressure measuring transducer of FIG. 1—provided instead of or supplementally to hollow spaces 43 for accommodating adsorptive bodies 13. Hollow space 49 is here annular and surrounds the exterior of pressure sensor 11. The boundary of hollow space 49 is formed here by a partition 51, which is permeable to the liquid and impermeable to adsorptive bodies 13; partition 51 is solidly connected to an inner lateral surface 53 of transducer housing 7 surrounding pressure measuring chamber 9 and to an end face 55 of pressure measuring chamber 9. End face 55 adjoins inner lateral surface 53 of the pressure measuring transducer on the side facing the pressure transfer means and closes the pressure measuring chamber on this side.

FIG. 5 shows two additional hollow spaces 57, 59, which can be applied instead of or supplementally to the hollow spaces 43, 49 described above. These two additional hollow spaces 57, 59 adjoin line 5 of the pressure measuring transducer of FIG. 1 and serve for for accommodating adsorptive bodies 13.

The hollow spaces 57, 59 containing adsorptive bodies 13 are arranged in the interior of a connection piece 61 of the pressure measuring transducer. Connection piece 61 connects measuring transducer housing 7 to the upstream pressure transfer means and a portion of line 5 extends through connection piece 61.

Hollow space 57 directly borders the portion of line 5 and is separated from this by a partition 63, which is permeable to the liquid and impermeable to adsorptive bodies 13.

Hollow space 59 is integrated in a region of filling opening 29 adjoining line 5. FIG. 5 shows filling opening 29 to be already sealed by a closure 65. Hollow space 59 is also closed here by a partition 67, which is permeable to the liquid and impermeable to adsorptive bodies 13. Preferably, hollow space 59 is formed by a cylindrical insert 69 fitted terminally into filling opening 29. Adsorptive bodies 13 are enclosed in cylindrical insert 69. Insert 69 is closed on the pressure transfer line side by partition 67 and on its side facing away from pressure transfer line 5 by an additional partition 71, which is permeable to the liquid and impermeable to adsorptive bodies 13.

This offers the advantage that insert 69 with adsorptive bodies 13 can be introduced into filling opening 29 before filling the inner space of the pressure transfer means. Therewith the option is provided to heat the inner space and the adsorptive bodies 13 under vacuum before the filling, and then to fill the inner space under vacuum via insert 69. In this way, adsorptive bodies 13 have their maximum adsorption capacity at the beginning of the filling procedure. A further advantage is that the entire amount of liquid to be filled flows over adsorptive bodies 13 into the inner space, and, in such case, foreign molecules dissolved in the liquid are adsorbed by the adsorptive bodies 13.

Adsorptive bodies 13, which remain in the inner space of the pressure measuring transducer, respectively in the adjoining hollow spaces 43, 49, 57, 59, during measurement operation offer the additional advantage that they can also adsorb foreign molecules that initially cling to the inner walls of the inner space or hollow spaces 43, 49, 57, 59 and, under certain circumstances, only detach after a long time and then enter the liquid.

Alternatively or supplementally to the granular adsorptive bodies 13 described above, also individual adsorptive bodies with greater dimensions, e.g. adsorptive bodies embodied as one piece, molded parts, can be applied in the pressure measuring transducer. These adsorptive bodies are preferably sintered zeolite inlays, which, for their respective location of use in the inner space of the pressure measuring transducer and/or in an adjoining hollow space opened to the inner space but otherwise outwardly closed, can be manufactured to accurately fit in the pressure measuring transducer.

FIG. 6 shows an example of an embodiment for this, in which a first adsorptive body 73 is arranged in a hollow space 75 forming the outer termination of pressure receiving chamber 3 of the pressure transfer means of FIG. 1 on the side of pressure receiving chamber 3 lying opposite isolating diaphragm 1. Adsorptive body 73 is essentially washer shaped and fills hollow space 75. Preferably, the side of adsorptive body 73 pointing into pressure receiving chamber 3 is formed as a diaphragm bed, against which isolating diaphragm 1 rests in the case of excess pressure acting thereon. This adsorptive body 73 serves both for the adsorption of foreign molecules as well as also for the protection of isolating diaphragm 1 in the case of overloads acting thereon.

Additionally provided in FIG. 6 is a second, tubular adsorptive body 77, which is inserted into the line 5 connecting pressure receiving chamber 3 to pressure measuring chamber 9.

FIG. 7 shows a further example of an embodiment, in which an adsorptive body 79 is arranged in pressure measuring chamber 9. Adsorptive body 79 fills out a relatively large part of the inner space of pressure measuring chamber 9 while leaving pressure sensor 11 and its connection to the pressure supply (not shown here), e.g. pressure receiving chamber 3, free. Also, this adsorptive body 79 fulfills a double function, in that, on the one hand, it adsorbs foreign molecules, and, on the other hand, it serves as a displacement body, whose insertion clearly reduces the amount of pressure transfer liquid required to fill pressure measuring chamber 9. Correspondingly formed adsorptive bodies can be applied in all sections of the inner spaces of pressure measuring transducers as well as in the hollow spaces of pressure measuring transducers, which border the inner spaces and open to the respective inner space but are otherwise closed outwardly, in which previously classic, purely mechanical, displacement bodies were applied.

Preferably, adsorptive body 79 is provided with electrical connections 81, via which electrical capacitance of adsorptive body 79 can be measured by a capacitance measuring circuit 83 connected thereto. Since adsorptive bodies 79 have an extremely porous structure, adsorptive body 79 is saturated after the filling of the pressure transfer liquid. Correspondingly the capacitance of adsorptive body 79 is a measure for the capacitance of the pressure transfer liquid, which, in turn, delivers information concerning the state of the pressure transfer liquid. Correspondingly, the state of the pressure transfer liquid can be monitored based on the measured capacitance of adsorptive body 79.

Via the capacitance measurement, it is recognizable directly after the filling of the pressure measuring transducer whether, as regards the adsorption of the foreign molecules by adsorptive body 79, a stable equilibrium state has been achieved. Moreover, based on the capacitance measurement, an increase in the content of foreign molecules, especially air and moisture, arising in the pressure transfer liquid in the area of adsorptive body 79 during the operational period of the pressure measuring transducer can be detected. Such a subsequent increase can be caused e.g. by damage to isolating diaphragm 1 or an unsealed site in the pressure measuring transducer.
1 isolating diaphragm
3 pressure receiving chamber
5 pressure transfer line
7 measuring transducer housing
9 pressure measuring chamber
11 pressure sensor
13 adsorptive body
15 supply container
17 mixer
19 remaining inner space of the supply container
21 vacuum pump
23 valve
25 outflow
27 filter
29 filling opening
31 evacuation line
33 filling line
35 measuring transducer housing
37 isolating diaphragm
39 pressure receiving chamber
41 pressure measuring chamber
43 hollow space
45 diaphragm bed
47 partition
49 hollow space
51 partition
53 interior lateral surface of the measuring transducer housing
55 interior end face of the measuring transducer housing
57 hollow space
59 hollow space
61 connection piece
63 partition
65 closure
67 partition
69 cylindrical insert
71 partition
73 adsorptive body
75 hollow space
77 adsorptive body
79 adsorptive body
81 electrical connection
83 capacitance measuring circuit

1-15. (canceled)

16. A method for reducing the content of foreign molecules in gaseous or liquid form dissolved in a pressure transfer liquid of a pressure measuring transducer, comprising the steps of:
providing a pressure receiving chamber closed by an isolating diaphragm;
providing a pressure measuring chamber connected to the pressure receiving chamber;
providing a pressure sensor arranged in the pressure measuring chamber, wherein the liquid serves to fill an inner space of the pressure measuring transducer formed by the pressure receiving chamber and the pressure measuring chamber connected thereto; and
transferring an external pressure acting on the isolating diaphragm to the pressure sensor in measurement operation, wherein
the liquid is brought into contact with at least one adsorptive body, and foreign molecules dissolved in the liquid are bound to the adsorptive bodies by adsorption.

17. The method as claimed in claim 16, wherein:
the adsorptive bodies comprise zeolite.

18. The method as claimed in claim 16, wherein:
the adsorptive bodies, in a pretreatment method for pretreating the liquid for filling the pressure measuring transducer, are introduced as granular material into the liquid, where the adsorptive bodies then adsorb foreign molecules;
the liquid is separated from the adsorptive bodies (13) containing the adsorbed gas molecules; and
the inner space of the pressure measuring transducer to be filled is filled with the liquid, which has been separated from the adsorptive bodies.

19. The method as claimed in claim 16, wherein:
the adsorptive bodies have a particle size, which is small compared to the dimensions of the inner space of the pressure measuring transducer to be filled;
the adsorptive bodies are introduced into the liquid in a pretreatment method for pretreating the liquid for filling the pressure measuring transducer; and
the inner space of the pressure measuring transducer is filled with the liquid containing the adsorptive bodies.

20. The method as claimed in claim 16, wherein:
the adsorptive bodies have a particle size, which is small compared to the dimensions of the inner space of the pressure measuring transducer to be filled;
the adsorptive bodies are introduced into the inner space of the pressure measuring transducer to be filled; and
the inner space is filled with the liquid.

21. The method as claimed in claim 16, wherein:
the pressure measuring transducer has at least one hollow space adjoining the inner space to be filled;
adsorptive bodies are introduced into the hollow spaces;
the hollow spaces are separated from the inner space by a partition, which is permeable to the liquid and impermeable to the adsorptive bodies; and
the inner space and the hollow spaces are filled with the liquid.

22. The method as claimed in claim 20, wherein:
the pressure transfer liquid is pretreated in a pretreatment method before filling the pressure measuring transducer with this liquid, the pretreatment method comprises:
adsorptive bodies are introduced into the liquid and adsorb foreign molecules dissolved therein;
the liquid is separated from the adsorptive bodies and the foreign molecules bound to the adsorptive bodies by adsorption; and
the separated liquid, which is free of adsorptive bodies, is used for filling.

23. A pressure measuring transducer, comprising:
a pressure receiving chamber closed by an isolating diaphragm;
a pressure measuring chamber connected to said pressure receiving chamber;
a pressure sensor arranged in said pressure measuring chamber; and
an inner space formed by said pressure receiving chamber and said pressure measuring chamber connected thereto and filled with a pressure transfer liquid, wherein:
the liquid contains adsorptive bodies, whose particle size is small compared to the dimensions of the inner space filled with the liquid, and which serve to bind foreign molecules dissolved in the liquid to themselves through adsorption.

24. The pressure measuring transducer, comprising:
an isolating diaphragm;
a pressure receiving chamber closed by said isolating diaphragm, a pressure measuring chamber connected to said pressure receiving chamber;
a pressure sensor arranged in said pressure measuring chamber; and
at least one hollow space adjoining the inner space formed by said pressure receiving chamber and said pressure measuring chamber connected thereto, wherein:
adsorptive bodies are arranged in said hollow spaces;
said inner space and said hollow spaces are filled with the pressure transfer liquid; and
said hollow spaces are separated from said inner space by a partition, which is permeable to the liquid and impermeable to said adsorptive bodies.

25. The pressure measuring transducer as claimed in claim 24, wherein:
at least one hollow space arranged in a diaphragm bed of said isolating diaphragm, which diaphragm bed adjoins said pressure receiving chamber;
at least one hollow space adjoins said pressure measuring chamber;
at least one hollow space adjoins a pressure transfer line connecting said pressure receiving chamber to said pressure measuring chamber; and/or
a hollow space, arranged in an end of a filling opening of the pressure measuring transducer and adjoins the inner space of the pressure measuring transducer.

26. The pressure measuring transducer, comprising:
an isolating diaphragm;
a pressure receiving chamber closed by said isolating diaphragm;
a pressure measuring chamber connected to said pressure receiving chamber; and
a pressure sensor arranged in said pressure measuring chamber, wherein:
the inner space formed by said pressure receiving chamber and said pressure measuring chamber connected therewith is filled with a pressure transfer liquid; and
at least one adsorptive body in the form of a molded body is arranged in said inner space or an adjoining hollow space.

27. The pressure measuring transducer as claimed in claim 26, wherein:
one of said adsorptive bodies is an adsorptive body that is arranged in a hollow space, which is closed to the environment, that adjoins said pressure receiving chamber on its side lying opposite said isolating diaphragm, and that is embodied as a diaphragm bed for said isolating diaphragm.

28. The pressure measuring transducer as claimed in claim 26, wherein:
one of said adsorptive bodies is a tubular adsorptive body inserted in a pressure transfer line connecting said pressure receiving chamber to said pressure measuring chamber.

29. The pressure measuring transducer as claimed in claim 26, wherein:
one of said adsorptive bodies is a displacement body inserted in said inner space of the pressure measuring transducer.

30. The pressure measuring transducer as claimed in claim 29, wherein:
said adsorptive body inserted as a displacement body is provided with electrical connections, via which a capacitance of said adsorptive body dependent on the state of the pressure transfer liquid soaking said adsorptive body can be measured by means of a capacitance measuring circuit (83) connected thereto.
